(19) United States
(12) Patent Application Publication
(10) Pub. No.: US 2025/0338748 A1
(43) Pub. Date: Oct. 30, 2025

(54) DISPLAY DEVICE AND MANUFACTURING METHOD THEREOF

(71) Applicant: SAMSUNG DISPLAY CO., LTD., YONGIN-SI (KR)

(72) Inventor: Yung Bin CHUNG, Yongin-si (KR)

(21) Appl. No.: 19/077,204

(22) Filed: Mar. 12, 2025

(30) Foreign Application Priority Data
Apr. 24, 2024 (KR) 10-2024-0054630

(51) Int. Cl. H10K 59/40; H10K 59/12; H10K 59/131

(52) U.S. Cl. CPC H10K 59/40; H10K 59/1201; H10K 59/131

(57) ABSTRACT

A display device includes: a substrate; pixels formed on the substrate; a base layer formed on the pixels; a first conductive pattern disposed on the base layer; a touch insulating layer formed on the base layer and the first conductive pattern and having contact holes that overlap portions of the first conductive pattern; and second conductive patterns formed on the touch insulating layer and electrically connected to the first conductive pattern through the contact holes, wherein some of the second conductive patterns are formed inside the contact holes, and the second conductive patterns include MXenes.

### CROSS-REFERENCE TO RELATED APPLICATION

This application claims priority under 35 U.S.C. § 119 (a) to Korean Patent Application No. 10-2024-0054630, filed on Apr. 24, 2024 in the Korean Intellectual Property Office, the disclosure of which is incorporated by reference herein in its entirety.

### TECHNICAL FIELD

The present invention relates to a display device and a manufacturing method thereof.

### DISCUSSION OF THE RELATED ART

As the desire for information to be displayed increases and a demand for using a portable information medium increases, research and commercialization for a display device has been under continuous development.

Generally, recent display devices are provided with a touch sensor to receive a user's touch input in addition to an image display function. For example, touch panels are being widely used with the spread of mobile electronic devices such as smartphones and tablet computers. As touch panels become widely used, technologies to increase the accuracy of touch detection and the speed of response to a touch are desirable.

For example, the touch panel's parasitic capacitor and high resistance may increase resistive-capacitive (RC) delay, making it difficult to detect signals and resulting in a low response speed to a touch. Accordingly, research to improve RC delay is being conducted. For example, RC delay may be improved by forming a thick touch insulating layer. However, in this case, as the thickness of the touch insulating layer increases, defects may occur due to the non-contact phenomenon of the conductive layer.

### SUMMARY

According to an embodiment of the present invention, a display device includes: a substrate; pixels formed on the substrate; a base layer formed on the pixels; a first conductive pattern disposed on the base layer; a touch insulating layer formed on the base layer and the first conductive pattern and having contact holes that overlap portions of the first conductive pattern; and second conductive patterns formed on the touch insulating layer and electrically connected to the first conductive pattern through the contact holes, wherein some of the second conductive patterns are formed inside the contact holes, and the second conductive patterns include MXenes.

In an embodiment of the present invention, the second conductive patterns includes a (2-1)-th conductive pattern and a (2-2)-th conductive pattern, wherein each of the (2-1)-th and (2-2)-th conductive patterns includes: a first portion formed on the touch insulating layer; and a second portion formed inside one of the contact holes, and the second portion includes the MXenes.

In an embodiment of the present invention, the first portion includes the MXenes.

In an embodiment of the present invention, the second portion includes a coating layer that is disposed on an inner surface of one of the contact holes and has the MXenes, and the MXenes of the coating layer has a first concentration.

In an embodiment of the present invention, the second portion includes a via layer that is formed on the coating layer and has the MXenes, and the MXenes of the via layer has a second concentration that is different from the first concentration.

In an embodiment of the present invention, the first concentration is lower than the second concentration.

In an embodiment of the present invention, the coating layer extends along the inner surface of the one of the contact holes to contact the first conductive pattern.

In an embodiment of the present invention, the coating layer extends from the inner surface of the one of the contact holes to contact an upper surface of the touch insulating layer and is included in the first portion.

In an embodiment of the present invention, the second conductive patterns include an inorganic compound with a two-dimensional planar structure.

In an embodiment of the present invention, the contact holes penetrate the touch insulating layer between one of the second conductive patterns and the first conductive pattern and between the other one of the second conductive patterns and the first conductive pattern.

In an embodiment of the present invention, the contact holes have an aspect ratio of 1 or more.

In an embodiment of the present invention, the touch insulating layer includes an organic insulating material.

According to an embodiment of the present invention, a manufacturing method of a display device includes: providing a substrate; forming pixels on the substrate; providing a base layer on the pixels; forming a first conductive pattern on the base layer; forming a touch insulating layer having contact holes that overlap portions of the first conductive pattern on the base layer; and forming second conductive patterns on the touch insulating layer, wherein the second conductive patterns are electrically connected to the first conductive pattern through the contact holes, wherein some of the second conductive patterns are formed inside the contact holes, and the second conductive patterns include MXenes.

In an embodiment of the present invention, the forming of the second conductive patterns further includes curing the MXenes at a low temperature.

In an embodiment of the present invention, the contact holes have an aspect ratio of 1 or more.

According to an embodiment of the present invention, a display device includes: a display panel; and a sensing panel disposed on the display panel, wherein the sensing panel includes: a base layer; a first conductive pattern disposed on the base layer; a touch insulating layer formed on the base layer and having first and second contact holes that overlap portions of the first conductive pattern; and (2-1)-th and (2-2)-th second conductive patterns formed on the touch insulating layer and electrically connected to the first conductive pattern through the first and second contact holes, wherein the (2-1)-th and (2-2)-th second conductive patterns are respectively disposed in the first and second contact holes, and each of the (2-1)-th and (2-2)-th second conductive patterns include MXenes.

In an embodiment of the present invention, each of the (2-1)-th and (2-2)-th second conductive patterns includes a coating layer and a via layer, wherein the coating layer is disposed on the touch insulating layer and inside the first and second contact holes, and wherein via layer is disposed on the coating layer.

In an embodiment of the present invention, the via layer is disposed inside the first and second contact holes.

In an embodiment of the present invention, the coating layer contacts the first conductive pattern.

In an embodiment of the present invention, the coating layer is disposed between the via layer and the first conductive pattern.

### BRIEF DESCRIPTION OF THE DRAWINGS

The above and other features of the present invention will become more apparent by describing in further detail embodiments thereof with reference to the accompanying drawings, in which:

FIG. 1 illustrates a perspective view of a display device according to an embodiment of the present invention.

FIG. 2 illustrates a cross-sectional view taken along line I-I′ of FIG. 1.

FIG. 3 illustrates a cross-sectional view of a display panel of FIG. 2 according to an embodiment of the present invention.

FIG. 4 illustrates a cross-sectional view of a sensing panel of FIG. 2 according to an embodiment of the present invention.

FIG. 5 illustrates a block diagram of the display device of FIG. 1 according to an embodiment of the present invention.

FIG. 6 illustrates a circuit diagram of a sub-pixel included in the display device of FIG. 1 according to an embodiment of the present invention.

FIG. 7 illustrates a top plan view of a display panel of the display device of FIG. 1 according to an embodiment of the present invention.

FIG. 8 illustrates a top plan view of a sensing panel of the display device of FIG. 1 according to an embodiment of the present invention.

FIG. 9 illustrates an enlarged view of portion “A” of FIG. 8 according to an embodiment of the present invention.

FIG. 10 illustrates a cross-sectional view taken along line II-II′ of FIG. 9.

FIG. 11 and FIG. 12 illustrate cross-sectional views taken along line III-III′ of FIG. 9.

FIGS. 13, 14, 15, 16 and 17 illustrate a manufacturing method of the display device according to an embodiment of the present invention.

### DETAILED DESCRIPTION OF THE EMBODIMENTS

Hereinafter, example embodiments of the present invention will be described in detail with reference to the accompanying drawings. In addition, the present invention may be embodied in different forms and is not limited to the embodiments set forth herein. In the figures and specification, like reference numerals may denote like elements or features, and thus their descriptions may be omitted.

Throughout the specification, when it is described that an element is “connected” to another element, this includes not only being “directly connected”, but also being “indirectly connected” with another device therebetween. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various elements, these elements should not be limited by these terms. These terms are used to distinguish one element from another. Thus, a first element discussed below could be termed a second element without departing from the teachings of the present invention.

Spatially relative terms, such as “beneath,” “below,” “lower,” “above,” “upper,” and the like, may be used herein for descriptive purposes, and, thereby, to describe a relationship between one element or feature and another element(s) or features(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, thus, the spatially relative descriptors used herein interpreted accordingly.

Various embodiments of the present invention are described herein with reference to illustrations that are schematic illustrations of embodiments. As such, variations from the shapes of the illustrations as a result, for example, of manufacturing techniques and/or tolerances, are to be expected. Thus, embodiments of the present invention disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

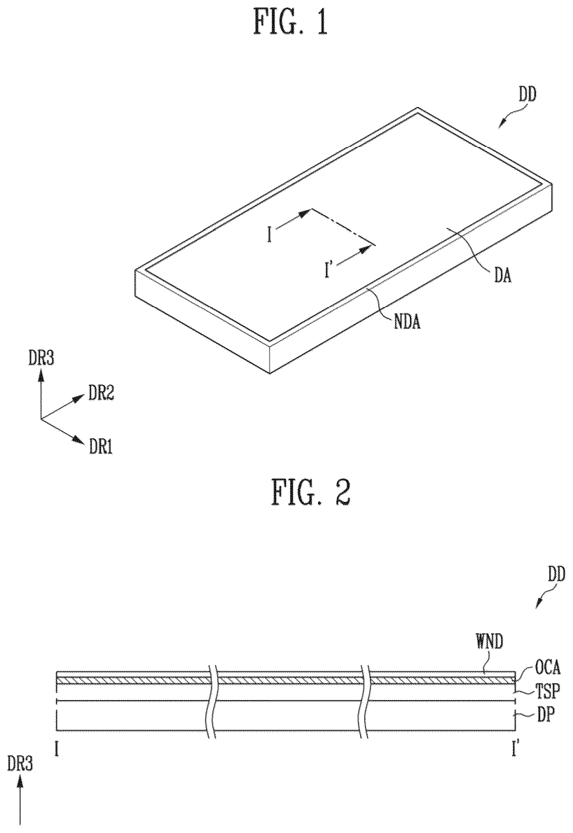

FIG. 1 illustrates a perspective view of a display device according to an embodiment of the present invention.

Referring to FIG. 1, when the display device DD is one in which a display surface is applied to one surface thereof such as a smart phone, a television, a tablet PC, a mobile phone, an image phone, an electron book reader, a desktop PC, a laptop PC, a netbook computer, a workstation, a server, a PDA, a portable multimedia player (PMP), an MP3 player, a medical device, a camera, or a wearable device, the present invention may be applied thereto.

The display device DD may be provided in various shapes, and as an example, may be provided in a rectangular plate shape having two pairs of sides that are parallel to each other, but the present invention is not limited thereto. For example, when the display device DD is provided in the rectangular plate shape, sides of one pair of the two pairs of sides may be provided to be longer than sides of the other pair thereof. In addition, in FIG. 1, the display device DD is shown as having angled corners made of straight lines, but the present invention is not limited thereto. For example, in the display device DD provided in a shape of a rectangular plate, a corner at which one long side and one short side contact each other may have a round shape.

In the embodiment, for better understanding and ease of description, the display device DD may have a rectangular shape having a pair of long sides and a pair of short sides. In this case, the extension direction of the long side may be indicated as a second direction DR2, the extension direction of the short side may be indicated as a first direction DR1, and the direction substantially perpendicular to the extension directions of the long side and the short side may be indicated as a third direction DR3. The first to third directions DR1 to DR3 may refer to directions indicated by the first to third directions DR1 to DR3, respectively.

In the embodiment, at least a portion of the display device DD may have flexibility, and the display device DD may be folded at the portion having the flexibility.

The display device DD may include a display area DA for displaying an image and a non-display area NDA that is provided adjacent to at least one side of the display area DA. The non-display area NDA may be an area in which images are not displayed. However, the present invention is not limited thereto. In embodiments of the present invention, a shape of the display area DA and a shape of the non-display area NDA may be correspondingly designed. For example, the non-display area NDA may be designed with a shape that surrounds a shape of the display area DA.

FIG. 2 illustrates a cross-sectional view taken along line I-I′ of FIG. 1.

Referring to FIG. 2, the display device DD may include a display panel DP, a sensing panel TSP (or, e.g., a touch sensor), and a window WND.

The display panel DP may display an image through the display area DA (see FIG. 1). The display panel DP may be a self-emission display panel such as an organic light emitting display panel (OLED panel) using an organic light emitting diode as a light emitting element, a nano-scale LED display panel using an ultra small light emitting diode as a light emitting element, or a quantum dot organic light emitting display panel (QD OLED panel) using a quantum dot and an organic light emitting diode may be used. In addition, as the display panel DP, a non-light emitting display panel such as a liquid crystal display panel (LCD panel), an electro-phoretic display panel (EPD panel), and an electro-wetting display panel (EWD panel). When a non-light emitting display panel is used as the display panel DP, the display device DD may include a backlight unit that supplies light to the display panel DP.

The sensing panel TSP may be disposed on the display panel DP to receive a user's touch input. The sensing panel TSP may sense the touch input by using a mutual capacitance method, or may sense the touch input by using a self-capacitance method.

The window WND for protecting an exposed surface of the display device DD may be provided on the display panel DP and the sensing panel TSP. The window WND may protect the display panel DP and the sensing panel TSP from external impact, and may provide an input surface and/or a display surface to a user. The window WND may be combined with the display panel DP and the sensing panel TSP by using an optically clear adhesive OCA.

The window WND may have a multi-layered structure including at least one of, for example, a glass substrate, a plastic film, and/or a plastic substrate. The multi-layered structure may be formed through a continuous process or an adhesive process using an adhesive layer. The window WND may be entirely or partially flexible.

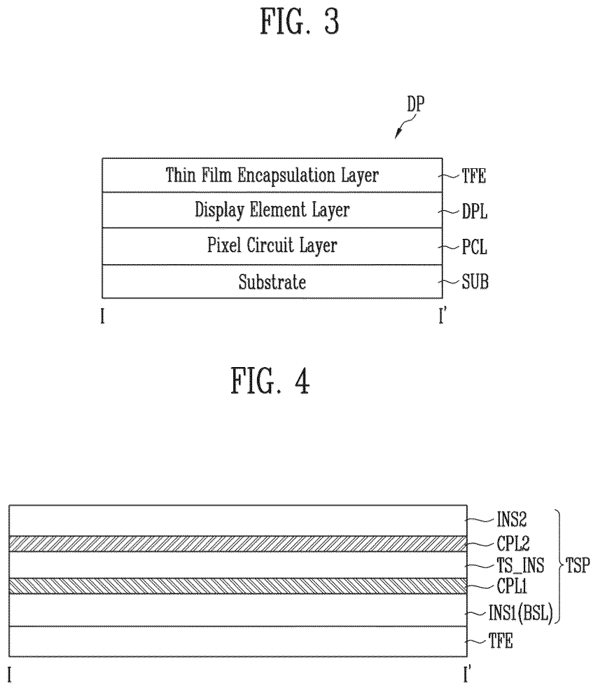

FIG. 3 illustrates a cross-sectional view of a display panel of FIG. 2 according to an embodiment of the present invention.

Referring to FIG. 3, the display panel DP may include a substrate SUB, a pixel circuit layer PCL, a display element layer DPL, and a thin film encapsulation layer TFE.

The substrate SUB may be a rigid substrate or a flexible substrate. When the substrate SUB is a rigid substrate, it may be one of a glass substrate, a quartz substrate, a glass ceramic substrate, or a crystalline glass substrate. When the substrate SUB is a flexible substrate, it may be one of a film substrate including a polymer organic material or a plastic substrate. In addition, the substrate SUB may include a fiber glass reinforced plastic (FRP).

The pixel circuit layer PCL may be disposed on the substrate SUB. In the pixel circuit layer PCL, a plurality of thin film transistors and wires connected to the thin film transistors may be disposed. For example, each thin film transistor may have a structure in which a semiconductor layer, a gate electrode, and a source/drain electrode are sequentially stacked with an insulating layer interposed between the semiconductor layer and the gate electrode and an insulating layer interposed between the gate electrode and the source/drain electrode. The semiconductor layer may include, for example, an amorphous silicon, a poly silicon, a low temperature poly silicon, and an organic semiconductor. Each of the gate electrode and the source/drain electrode may include at least one of aluminum (Al), copper (Cu), titanium (Ti), and/or molybdenum (Mo), but the present invention is not limited thereto. In addition, the pixel circuit layer PCL may include at least one or more insulating layers.

The display element layer DPL may be disposed on the pixel circuit layer PCL. The display element layer DPL may include a light emitting element that emits light. The light emitting element may be, for example, an organic light emitting diode, but the present invention is not limited thereto. In embodiments of the present invention, the light emitting element may be an inorganic light emitting element including an inorganic light emitting material or a light emitting element (quantum dot display element) that emits light by changing a wavelength of light emitted by using a quantum dot.

The thin film encapsulation layer TFE may be disposed on the display element layer DPL. The thin film encapsulation layer TFE may be an encapsulation substrate or a multi-layered encapsulation film. When the thin film encapsulation layer TFE is in a form of the encapsulation film, the thin film encapsulation layer TFE may include an inorganic film and/or an organic film. For example, the thin film encapsulation layer TFE may have a structure in which an inorganic film, an organic film, and an inorganic film are sequentially stacked. The thin film encapsulation layer TFE may prevent external air and moisture from penetrating into the display element layer DPL and the pixel circuit layer PCL.

FIG. 4 illustrates a cross-sectional view of a sensing panel of FIG. 2 according to an embodiment of the present invention.

Referring to FIG. 4, the sensing panel TSP (or, e.g., a touch sensor) may be disposed on a surface of the display panel DP in which an image is displayed to receive a user's touch input and/or hover input. For example, the sensing panel TSP may be directly disposed on a surface of the display panel DP. Here, “directly disposed” may mean formed through a continuous process, excluding attachment using a separate adhesive layer (or bonding layer).

The sensing panel TSP may detect touch capacitance by contact and/or proximity of a user's hand or a separate input member such as a conductor similar to the user's hand to recognize a touch input and/or a hover input of the display device DD. Here, the touch input may be a direct touch (or contact) by the user's hand or the separate input member, and the hover input may mean that the user's hand or the separate input member is near, but not touching, the display device DD that includes the sensing panel TSP.

The sensing panel TSP may include a first insulating layer INS1, a first conductive layer CPL1, a touch insulating layer TS_INS, a second conductive layer CPL2, and a second insulating layer INS2.

The first insulating layer INS1 may be a base layer BSL. The first insulating layer INS1 is a predetermined insulating film, and may be disposed on the thin film encapsulation layer TFE. The first insulating layer INS1 may be the uppermost layer of the thin film encapsulation layer TFE of the display panel DP. For example, the first insulating layer INS1 may be an insulating film that is an uppermost layer of the thin film encapsulation layer TFE. According to an embodiment of the present invention, the first insulating layer INS1 may be an insulating film that is disposed on the thin film encapsulation layer TFE.

The touch insulating layer TS_INS may be interposed between the first conductive layer CPL1 and the second conductive layer CPL2. The touch insulating layer TS_INS may have a predetermined thickness for improving RC delay. For example, the touch insulating layer TS_INS may have a thickness of about 100 μm or less, but the present invention is not limited thereto.

The first conductive layer CPL1 may be disposed on the first insulating layer INS1. The second conductive layer CPL2 may be disposed on the first conductive layer CPL1 with the touch insulating layer TS_INS interposed therebetween. The second insulating layer INS2 may be disposed on the second conductive layer CPL2.

The first conductive layer CPL1 may be implemented as a single layer. In this case, the first conductive layer CPL1 may include a metal layer or a transparent conductive layer. For example, the metal layer may include molybdenum, silver, titanium, copper, aluminum, and an alloy thereof. The transparent conductive layer may include, for example, a transparent conductive oxide such as an indium tin oxide (ITO), an indium zinc oxide (IZO), a zinc oxide (ZnO), and an indium tin zinc oxide (ITZO). In addition, the transparent conductive layer may include PEDOT, a metal nano wire, and graphene.

The first conductive layer CPL1 may be implemented as a multilayer. In this case, the first conductive layer CPL1 may include a multi-layered metal layer. For example, the multi-layered metal layer may have a three-layered structure of titanium (Ti)/aluminum (Al)/titanium (Ti).

The second conductive layer CPL2 may be implemented as a single layer. In this case, the second conductive layer CPL2 may include a transparent conductive layer. According to an embodiment of the present invention, the transparent conductive layer may include an inorganic compound with a two-dimensional planar structure, such as MXenes.

The second conductive layer CPL2 may be implemented as a multilayer. In this case, the second conductive layer CPL2 may include a multi-layered conductive layer. For example, the multi-layered conductive layer may include at least one layer containing MXenes. For example, the multi-layered conductive layer may have a two-layered structure of MXenes/MXenes having different concentrations. However, the multi-layered conductive layer is not limited thereto. For example, the multi-layered conductive layer may have a two-layered structure of MXenes/indium tin oxide (ITO).

Each of the touch insulating layer TS_INS and the second insulating layer INS2 may include an inorganic insulating material or an organic insulating material, respectively. According to an embodiment of the present invention, the inorganic insulating material may include at least one of an aluminum oxide, a titanium oxide, a silicon oxide, a silicon nitride, a silicon oxynitride, a zirconium oxide, and/or a hafnium oxide. The organic insulating material may include at least one of, for example, an acrylic resin, a methacrylic resin, a polyisoprene resin, a vinyl resin, an epoxy resin, a urethane resin, a cellulose resin siloxane resin, a polyimide resin, a polyamide resin, and/or a perylene resin. According to an embodiment of the present invention, the touch insulating layer TS_INS may be an organic insulating layer including an organic insulating material.

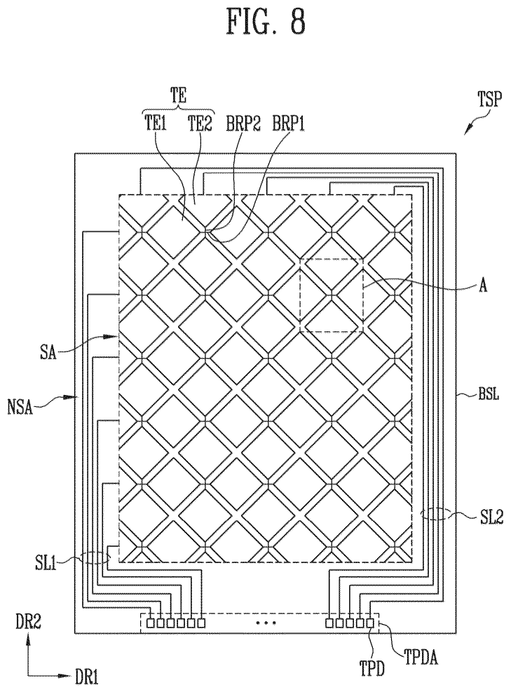

According to an embodiment of the present invention, the first conductive layer CPL1 and/or the second conductive layer CPL2 may include sensor electrodes (TE in FIG. 8), bridge patterns BRP1 and BRP2, and sensing wires (SL1 and SL2 in FIG. 8).

The second insulating layer INS2 may be a passivation layer disposed and/or formed on the second conductive layer CPL2. For example, the second insulating layer INS2 may be a passivation layer entirely disposed and/or formed on the second conductive layer CPL2. The second insulating layer INS2 may prevent corrosion of the second conductive layer CPL2 by preventing the second conductive layer CPL2 from being exposed to the outside.

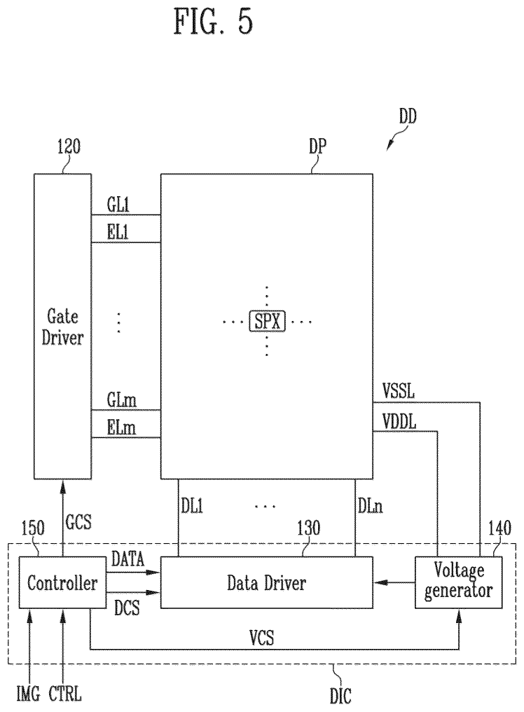

FIG. 5 illustrates a block diagram of the display device of FIG. 1 according to an embodiment of the present invention.

Referring to FIG. 5, a display device DD may include a display panel DP, a gate driver 120, a data driver 130, a voltage generator 140, and a controller 150.

The display panel DP may include sub-pixels SPX. The sub-pixels SPX may be connected to the gate driver 120 through first to m-th gate lines GL1 to GLm. The sub-pixels SPX may be connected to the data driver 130 through first to n-th data lines DL1 to DLn.

Each of the sub-pixels SPX may include at least one light emitting element that is configured to generate light. Accordingly, the sub-pixels SPX may respectively generate light of a specific color, such as red, green, blue, cyan, magenta, yellow, or the like.

The gate driver 120 may be connected to the sub-pixels SPX disposed in a row direction through the first to m-th gate lines GL1 to GLm. The gate driver 120 may output gate signals to the first to m-th gate lines GL1 to GLm in response to a gate control signal GCS. In embodiments of the present invention, the gate control signal GCS may include a start signal indicating the start of each frame, a horizontal synchronization signal for outputting gate signals in synchronization with the timing at which data signals are applied, and the like.

In embodiments of the present invention, first to m-th light emitting control lines EL1 to ELm connected to the sub-pixels SPX in a row direction may be further provided. In this case, the gate driver 120 may include a light emitting control driver configured to control the first to m-th light emitting control lines EL1 to ELm, and the light emitting control driver may operate under the control of the controller 150.

The data driver 130 may be connected to the sub-pixels SPX disposed in a column direction through the first to n-th data lines DL1 to DLn. The data driver 130 may receive image data (DATA) and a data control signal DCS from the controller 150. The data driver 130 may operate in response to the data control signal DCS. In embodiments of the present invention, the data control signal DCS may include a source start pulse, a source shift clock, a source output enable signal, and the like.

The data driver 130 may use voltages from the voltage generator 140 to apply data signals having grayscale voltages corresponding to the image data (DATA) to the first to n-th data lines DL1 to DLn. When a gate signal is applied to each of the first to m-th gate lines GL1 to GLm, data signals corresponding to the image data DATA may be applied to the data lines DL1 to DLn. Accordingly, the corresponding sub-pixels SPX may generate light corresponding to the data signals. Accordingly, an image may be displayed on the display panel DP.

In embodiments of the present invention, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device DD. For example, the voltage generator 140 may be configured to generate a plurality of voltages by receiving an input voltage from the outside of the display device DD, adjusting the received voltage, and regulating the adjusted voltage. The voltage generator 140 may generate a first power voltage and

a second power voltage. The first and second power voltages may be provided to the sub-pixels SPX through first and second power lines VDDL and VSSL, respectively. The first power voltage may have a relatively high voltage level, and the second power voltage may have a voltage level lower than the first power voltage VDD. In embodiments of the present invention, the first power voltage or the second power voltage VSS may be provided by an external device of the display device DD.

In addition, the voltage generator 140 may generate various voltages. For example, the voltage generator 140 may generate an initialization voltage that is applied to the sub-pixels SPX. For example, during a sensing operation to sense electrical characteristics of transistors and/or light emitting elements of the sub-pixels SPX, a predetermined reference voltage may be applied to the first to n-first data lines DL1 to DLn, and the voltage generator 140 may generate the reference voltage.

The controller 150 may control various operations of the display device DD. The controller 150 may receive input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments of the present invention, the controller 150 may output the image data DATA by aligning the input image data IMG to be suitable for the sub-pixels SPX of a row unit.

Two or more components of the data driver 130, the voltage generator 140, and the controller 150 may be mounted on one integrated circuit. As shown in FIG. 5, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In embodiments of the present invention, at least one of the data driver 130, the voltage generator 140, and/or the controller 150 may be provided as a component that is separated from the driver integrated circuit DIC.

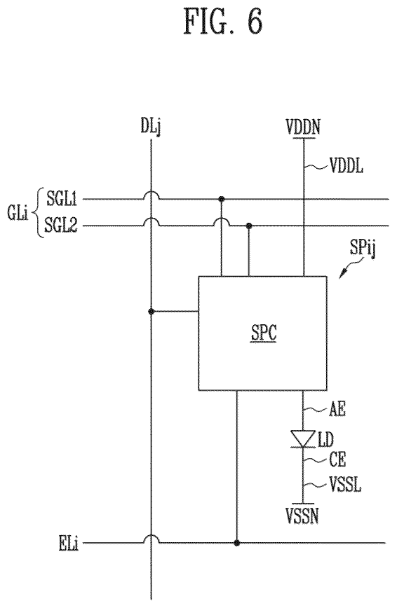

FIG. 6 illustrates a circuit diagram of a sub-pixel included in the display device of FIG. 1 according to an embodiment of the present invention.

In FIG. 6, among the sub-pixels SPX of FIG. 5, a sub-pixel SPXij disposed in an i-th row (i is an integer greater than or equal to 1 and less than or equal to m) and a j-th column (j is an integer greater than or equal to 1 and less than or equal to n) is illustrated as an example.

Referring to FIG. 6, the sub-pixel SPXij may include a sub-pixel circuit SPC and a light emitting element LD.

The light emitting element LD may be connected between a first power voltage node VDDN and a second power voltage node VSSN. The first power voltage node VDDN may be connected to the first power line VDDL to receive the first power voltage. The second power voltage node VSSN may be connected to the second power line VSSL to receive the second power voltage. The first power voltage may have a higher voltage level than the second power voltage.

The light emitting element LD may be connected between the anode electrode AE and the cathode electrode CE. The anode electrode AE may be connected to the first power voltage node VDDN through the sub-pixel circuit SPC. For example, the anode electrode AE may be connected to the first power voltage node VDDN through one or more transistors that are included in the sub-pixel circuit SPC. The cathode CE may be connected to the second power voltage node VSSN. The light emitting element LD may be configured to emit light according to a current flowing from the anode electrode AE to the cathode electrode CE.

The sub-pixel circuit SPC may be connected to an i-th gate line GLi of the first to m-th gate lines GL1 to GLm of FIG. 5 and a j-th data line DLj of the first to n-th data lines DL1 to DLn of FIG. 5. In response to the gate signal that is received through the i-th gate line GLi, the sub-pixel circuit SPC may control the light emitting element LD to emit light according to the data signal that is received through the j-th data line DLj. In embodiments of the present invention, the sub-pixel circuit SPC may be connected to the pixel control lines of FIG. 5. In this case, the sub-pixel circuit SPC may control the light emitting element LD in response to pixel control signals that are received through the pixel control lines.

For these operations, the sub-pixel circuit SPC may include circuit elements, such as transistors and one or more capacitors.

The transistors of the sub-pixel circuit SPC may include P-type transistors and/or N-type transistors. In embodiments of the present invention, the transistors of the sub-pixel circuit SPC may include a metal oxide silicon field effect transistor (MOSFET). In embodiments of the present invention, the transistors of the sub-pixel circuit SPC may include an amorphous silicon semiconductor, a monocrystalline silicon semiconductor, a polycrystalline silicon semiconductor, and an oxide semiconductor.

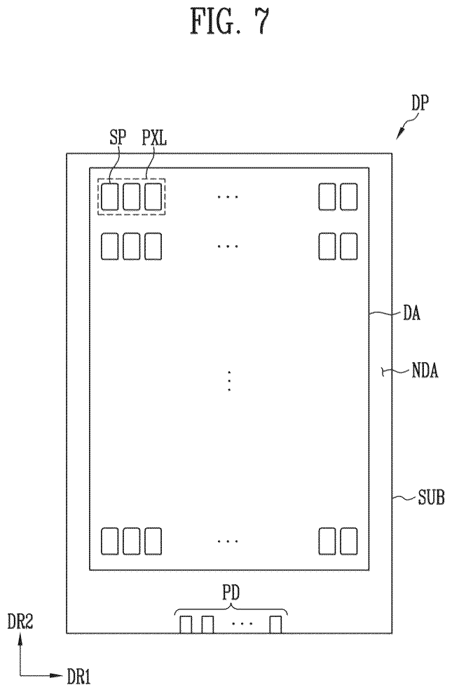

FIG. 7 illustrates a top plan view of a display panel of the display device of FIG. 1 according to an embodiment of the present invention.

Referring to FIG. 7, the display panel DP may include a display area DA and a non-display area NDA. The display panel DP may display an image through the display area DA. The non-display area NDA may be disposed adjacent to the display area DA.

The display panel DP may include a substrate SUB, sub-pixels SPX, and pads PD.

The sub-pixels SPX may be disposed in the display area DA on the substrate SUB. The sub-pixels SPX may be disposed in a matrix format along a first direction DR1 and a second direction DR2 that intersects the first direction DR1. However, embodiments of the present invention are not limited thereto. For example, the sub-pixels SPX may be disposed in a zigzag form along first direction DR1 and second direction DR2. For example, the sub-pixels SPX may be disposed in a PENTILE™ shape.

Two or more of the plurality of sub-pixels SPX may configure one pixel PXL. For example, three sub-pixels may configure one pixel PXL.

A constituent element to control the sub-pixels SPX may be disposed in the non-display area NDA on the substrate SUB. For example, wires connected to the sub-pixels SPX, such as the first to m-th gate lines GL1 to GLm and the first to n-th data lines DL1 to DLn of FIG. 5, may be disposed in the non-display area NDA.

At least one of the gate driver 120, the data driver 130, the voltage generator 140, and/or the controller 150 in FIG. 5 may be integrated in the non-display area NDA of the display panel DP. In embodiments of the present invention, the gate driver 120 of FIG. 5 may be mounted on the display panel DP, and may be disposed in the non-display area NDA. In embodiments of the present invention, the gate driver 120 may be implemented as an integrated circuit that is separated from the display panel DP.

The pads PD may be disposed in the non-display area NDA on the substrate SUB. The pads PD may be electrically connected to the sub-pixels SPX through wires. For example, the pads PD may be connected to the sub-pixels SPX through the first to n-th data lines DL1 to DLn.

The pads PD may interface the display panel DP to other constituent elements of the display device DD (see FIG. 1). In embodiments of the present invention, voltages and signals that are used for operations of constituent elements that are included in the display panel DP may be provided from the driver integrated circuit DIC of FIG. 5 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments of the present invention, the circuit board may be electrically connected to the pads PD by using a conductive adhesive member such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

In embodiments of the present invention, the display area DA may have various shapes. For example, the display area DA may have a closed-loop shape including sides of a straight line and/or a curved line. For example, the display area DA may have shapes such as a polygonal shape, a circular shape, a semicircular, and an elliptical shape.

In embodiments of the present invention, the display panel DP may have a flat display surface. In embodiments of the present invention, the display panel DP may have a display surface that is at least partially round. In embodiments of the present invention, the display panel DP may be bendable, foldable, or rollable. In these cases, the display panel DP and/or the substrate SUB may include materials that have flexible properties.

FIG. 8 illustrates a top plan view of a sensing panel of the display device of FIG. 1 according to an embodiment of the present invention.

Referring to FIG. 8, the sensing panel TSP may include a base layer BSL including a sensor area SA (or, e.g., a sensing area or an active area) or a non-sensor area NSA (or, e.g., a non-sensing area). The base layer BSL may further include a pad area TPDA.

The base layer BSL may include reinforced glass, transparent plastic, or transparent film. In embodiments of the present invention, the base layer BSL may include the same material as the substrate SUB of the display panel DP described above with reference to FIG. 3 and FIG. 7.

The sensor area SA may be provided in the central area of the base layer BSL to overlap the display area DA (see FIG. 1). The sensor area SA may be provided to have substantially the same shape as the shape of the display area DA, but the present invention is not limited thereto. The sensor area SA may detect a touch input. Sensor electrodes for detecting the touch input may be provided and/or formed in the sensor area SA.

The non-sensor area NSA may be provided in a peripheral area of the base layer BSL to overlap the non-display area NDA (see FIG. 7). Here, the peripheral area may be an area at least partially surrounding the central area of the base layer BSL. Sensing wires SL1 and SL2 that are electrically connected to the sensor electrodes TE to receive and transmit a sensing signal may be provided and/or formed in the non-sensor area NSA. In addition, a touch pad area TPDA, which includes touch pads TPD that are connected to the sensing wires SL1 and SL2 to be electrically connected to the sensor electrodes TE of the sensor area SA, may be disposed in the non-sensor area NSA. The sensing wires SL1 and SL2 may include a plurality of first sensing wires SL1 and a plurality of second sensing wires SL2.

The sensor electrodes TE may include a plurality of first sensor electrodes TE1 and a plurality of second sensor electrodes TE2 that are electrically insulated from the first sensor electrodes TE1.

The first sensor electrodes TE1 and the second sensor electrodes TE2 may include a conductive material. The conductive material may include at least one of, for example, a metal, an alloy of the metal, a conductive polymer, a conductive metal oxide, or a nano conductive material, but present invention is not limited thereto.

The first sensor electrodes TE1 are disposed in the first direction DR1. The first sensor electrodes TE1, which are adjacent to each other, may be electrically connected to each other through the first bridge pattern BRP1. The first sensor electrodes TE1 disposed in the row direction may configure one sensor row. The second sensor electrodes TE2 are disposed in the second direction DR2 intersecting the first direction DR1. The second sensor electrodes TE2, which are adjacent to each other, may be electrically connected to each other through the second bridge pattern BRP2. The second sensor electrodes TE2 disposed in the column direction may configure one sensor column.

The first and second sensor electrodes TE1 and TE2 may be electrically connected to the touch pads TPD through the corresponding sensing wires SL1 and SL2. The first sensor electrodes TE1 may be electrically connected to the touch pads TPD through the first sensing lines SL1. The second sensor electrodes TE2 may be electrically connected to the touch pads TPD through the second sensing lines SL2.

The first sensor electrodes TE1 may be driving electrodes that receive a driving signal for detecting a touch position in the sensor area SA, and the second sensor electrodes TE2 may be sensing electrodes that output a sensing signal for detecting a touch position in the sensor area SA. However, the present invention is not limited thereto. For example, the first sensor electrodes TE1 may be sensing electrodes, and the second sensor electrodes TE2 may be driving electrodes.

According to an embodiment of the present invention, the sensing panel TSP may sense the touch input by using a mutual capacitance method, or may sense the touch input by using a self-capacitance method.

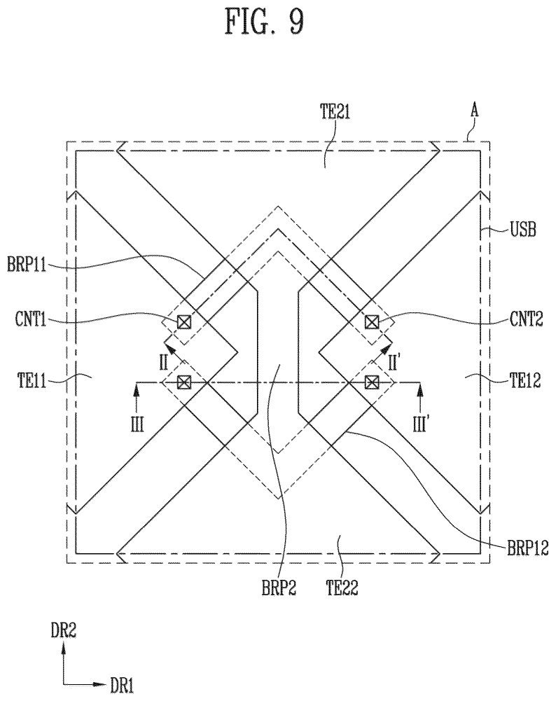

FIG. 9 illustrates an enlarged view of portion “A” of FIG. 8 according to an embodiment of the present invention.

Referring to FIG. 8 and FIG. 9, first bridge patterns BRP11 and BRP12 may electrically connect first sensor electrodes TE11 and TE12, which are adjacent to each other in the first direction DR1, to each other. The second bridge pattern BRP2 may electrically connect second sensor electrodes TE21 and TE22, which are adjacent to each other in the second direction DR2, to each other.

According to an embodiment of the present invention, the first bridge patterns BRP11 and BRP12 may be disposed on different layers from those of the first sensor electrodes TE11 and TE12. In this case, the first bridge patterns BRP11 and BRP12 may be connected to the first sensor electrodes TE11 and TE12 through contact holes CNT1 and CNT2. In addition, the second bridge pattern BRP2 may be integrally formed with the second sensor electrodes TE21 and TE22. The first sensor electrodes TE11 and TE12, the second sensor electrodes TE21 and TE22, and the second bridge pattern BRP2 may be disposed on the same layer as each other.

The sensing panel TSP may have a structure in which unit sensor blocks USB are repeatedly disposed. The unit sensor block USB may be a virtual unit block including a portion of the adjacent first sensor electrodes TE11 and TE12 and a portion of the adjacent second sensor electrodes TE21 and TE22. The unit sensor block USB may correspond to a minimum unit in which an arrangement pattern of the first sensor electrodes TE1 and the second sensor electrodes TE2 is repeated.

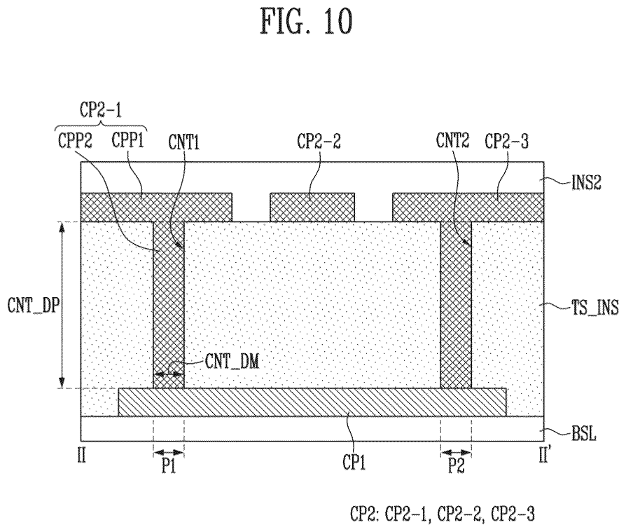

FIG. 10 illustrates a cross-sectional view taken along line II-II′ of FIG. 9.

Referring to FIG. 10, the base layer BSL (or first insulating layer INS1) may be provided on the thin film encapsulation layer TFE (see FIG. 4). For example, the base layer BSL may include an organic insulating film including an organic insulating material or an inorganic insulating film including an inorganic insulating material. In embodiments of the present invention, the base layer BSL might not be disposed on the thin film encapsulation layer TFE. Depending on the embodiment, a layer disposed on an uppermost portion of the thin film encapsulation layer TFE may be provided as the base layer BSL.

The first conductive pattern CP1 may be formed on the base layer BSL. The first conductive pattern CP1 may include the first bridge patterns BRP11 and BRP12 described above with reference to FIG. 9. For example, the first conductive pattern CP1 shown in FIG. 10 may be provided as the first bridge pattern BRP11. The first conductive pattern CP1 may include a conductive material. The conductive material may include, for example, a transparent conductive oxide or a metallic material, but the present invention is not limited thereto.

The second conductive patterns CP2 may be formed on the touch insulating layer TS_INS. The second conductive patterns CP2 may include the first sensor electrodes TE11 and TE12, the second sensor electrodes TE21 and TE22, and the second bridge pattern BRP2 described above with reference to FIG. 9. For example, the (2-1)-th conductive pattern CP2-1 illustrated in FIG. 10 may be provided as the first sensor electrode TE11, and the (2-3)-th conductive pattern CP2-3 may be provided as the first sensor electrode TE12. In addition, the (2-2)-th conductive pattern CP2-2 may be provided as the second sensor electrode TE21.

For example, the second conductive patterns CP2 may include MXenes. For example, the second conductive patterns CP2 may include an inorganic compound with a two-dimensional planar structure. For example, MXenes may be a nano-material that is composed of an atom-thick layer of carbon or nitrogen bonded to a transition metal in a two-dimensional planar structure. MXenes may include Mₙ₊₁Xₙ with a single transition metal and M′ₙ₊₁M″ₙ₊₁Xₙ with two or more types of transition metals. Here, M, M′, and M″ are transition metals, and X may be C, N, or a combination thereof. However, the type of MXenes is not limited thereto. Here, MXenes may be provided to prevent contact defects between the first conductive pattern CP1 and the second conductive patterns CP2 that are electrically connected to each other through the contact holes CNT1 and CNT2.

The touch insulating layer TS_INS may be disposed on the first conductive pattern CP1. The touch insulating layer TS_INS may be formed on the base layer BSL. For example, a portion of the touch insulating layer TS_INS may be spaced apart from the base layer BSL with the first conductive pattern CP1 interposed therebetween. Another portion of the touch insulating layer TS_INS may be formed to be in contact with the base layer BSL. The touch insulating layer TS_INS may include substantially the same material as the base layer BSL, but the present invention is not limited thereto.

In embodiments of the present invention, the touch insulating layer TS_INS may have contact holes CNT1 and CNT2 overlapping portions P1 and P2 of the first conductive pattern CP1. For example, the first contact hole CNT1 may penetrate the touch insulating layer TS_INS between the portion P1 of the first conductive pattern CP1 and the (2-1)-th conductive patterns CP2-1. The second contact hole CNT2 may penetrate the touch insulating layer TS_INS between the other portion P2 of the first conductive pattern CP1 and the (2-3)-th conductive patterns CP2-3. For example, the first contact hole CNT1 and the second contact hole CNT2 may respectively overlap the (2-1)-th conductive patterns CP2-1 and the (2-3)-th conductive patterns CP2-3.

The contact holes CNT1 and CNT2 may have an aspect ratio of 1 or more. The depth CNT_DP of each of the contact holes CNT1 and CNT2 may be about 50 μm or more and about 100 μm or less. However, if the contact holes CNT1 and CNT2 have an aspect ratio of 1 or more, the contact holes CNT1 and CNT2 are not limited to the corresponding depth. For example, the contact holes CNT1 and CNT2 may have different diameters CNT_DM depending on differences in composition of the touch insulating layer TS_INS. Accordingly, the depth CNT_DP of the contact holes CNT1 and CNT2 may also vary. For example, when the diameter CNT_DM of the contact holes CNT1 and CNT2 is about 100 μm, the depth CNT_DP of the contact holes CNT1 and CNT2 may be about 100 μm or more. In this case, the aspect ratio of the contact holes CNT1 and CNT2 may be 1 or more.

Some of the second conductive patterns CP2 may be formed inside the contact holes CNT1 and CNT2. For example, a portion of the (2-1)-th conductive pattern CP2-1 may be formed inside the first contact hole CNT1. For example, the (2-1)-th conductive pattern CP2-1 may be in contact with the first conductive pattern CP1 through the first contact hole CNT1. For example, a portion of the (2-3)—the conductive pattern CP2-3 may be formed inside the second contact hole CNT2. The (2-3)-th conductive pattern CP2-3 may be in contact with the first conductive pattern CP1 through the second contact hole CNT2.

The (2-1)-th and (2-3)-th conductive patterns CP2-1 and CP2-3 may be electrically connected to the first conductive pattern CP1 through the contact holes CNT1 and CNT2 of the touch insulating layer TS_INS. For example, the (2-1)-th conductive pattern CP2-1 may include a first portion CPP1, which is formed on the touch insulating layer TS_INS, and a second portion CPP2, which is formed inside the first contact hole CNT1. The first portion CPP1 and the second portion CPP2 may be provided as one connected conductive pattern. For example, the first portion CPP1 and the second portion CPP2 may be a single body. For example, the second portion CPP2 may be formed inside the first contact hole CNT1, and may include MXenes. At the lower portion of the first contact hole CNT1, the second portion CPP2 may be in contact with the first conductive pattern CP1. At the side surface portion of the first contact hole CNT1, the second portion CPP2 may be in contact with the touch insulating layer TS_INS. The first portion CPP1 may be formed on the touch insulating layer TS_INS and may include MXenes. Here, since the MXenes included in the (2-1)-th and (2-3)-th conductive patterns CP2-1 and CP2-3 have organic dispersion ink characteristics, they may be applied through a liquid process such as spray coating, spin coating, and inkjet printing. Through this liquid process, the inner surfaces of the first contact hole CNT1 may be coated with MXenes, which contain two-dimensional particles and maintain unique properties.

As such, the (2-1)-th and (2-3)-th conductive patterns CP2-1 and CP2-3 including MXenes having a low resistance and a high transmittance may be formed inside the contact holes CNT1 and CNT2 of the touch insulating layer TS_INS. For example, the first conductive pattern CP1 and the second conductive patterns CP2 may provide a more stable electrical connection through MXenes formed in the contact holes CNT1 and CNT2. In addition, the (2-1)-th and (2-3)-th conductive patterns CP2-1 and CP2-3 include MXenes instead of metal, thereby reducing light blocking by the metal pattern and increasing light efficiency.

The second insulating film INS2 may be formed on the touch insulating layer TS_INS and the second conductive patterns CP2. The second insulating film INS2 may protect the second conductive patterns CP2 from external environments. The second insulating film INS2 may provide a flat top surface.

In the above-described embodiments, it has been described as an example that the first bridge pattern BRP11 is included in the first conductive pattern CP1, and the first sensor electrodes TE11 and TE12 and the second sensor electrode TE21 are included in the second conductive patterns CP2, but the present invention is not limited thereto. According to an embodiment of the present invention, the first sensor electrodes TE11 and TE12 and the second sensor electrode TE21 may be included in the first conductive pattern CP1, and the first bridge pattern BRP11 may be included in the second conductive patterns CP2.

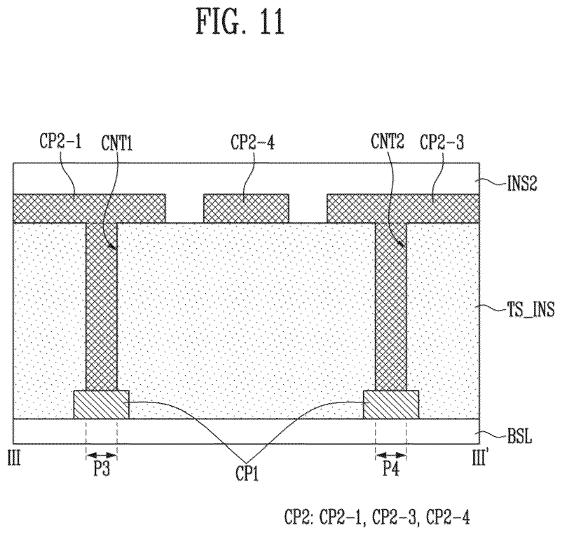

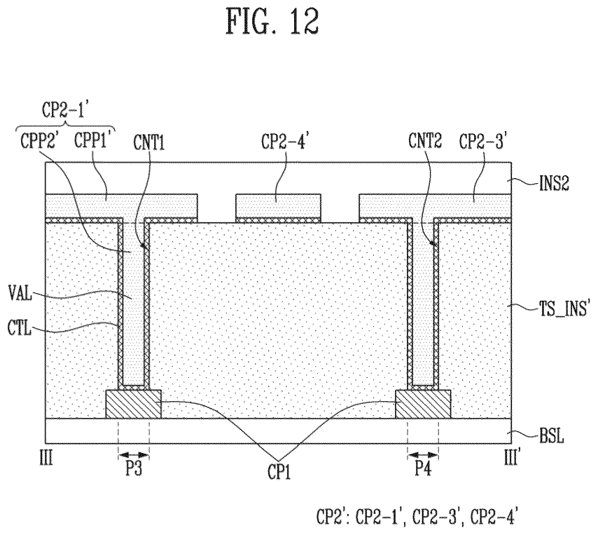

FIG. 11 and FIG. 12 illustrate cross-sectional views taken along line III-III of FIG. 9.

Referring to FIG. 9 and FIG. 11, the second conductive patterns CP2 may be formed on the touch insulating layer TS_INS. For example, the (2-1)-th conductive pattern CP2-1 illustrated in FIG. 11 may be provided as the first sensor electrode TE11, and the (2-3)-th conductive pattern CP2-3 may be provided as the first sensor electrode TE12. In addition, the (2-4)-th conductive pattern CP2-4 may be provided as the second bridge pattern BRP2. The second bridge pattern BRP2 may be a conductive pattern that is integrally provided with the second sensor electrodes TE21 and TE22 that are adjacent to each other.

According to an embodiment of the present invention, the contact holes CNT1 and CNT2 may include MXenes therein. The first contact hole CNT1 may penetrate the touch insulating layer TS_INS between the (2-1)—the conductive pattern CP2-1 and the first conductive pattern CP1. The first contact hole CNT1 may overlap a portion P3 of the first conductive pattern CP1. The second contact hole CNT2 may penetrate the touch insulating layer TS_INS between the (2-3)-th conductive pattern CP2-3 and the first conductive pattern CP1. The second contact hole CNT2 may overlap another portion P4 of the first conductive pattern CP1. The contact holes CNT1 and CNT2 and the (2-1)-th and (2-3)-th conductive patterns CP2-1 and CP2-3 may be configured similarly to FIG. 10.

Referring to FIG. 9 and FIG. 12, the second conductive patterns CP2′ may be formed on the touch insulating layer TS_INS′. For example, the (2-1)-th conductive pattern CP2-1′ illustrated in FIG. 12 may be provided as the first sensor electrode TE11, and the (2-3)-th conductive pattern CP2-3′ may be provided as the first sensor electrode TE12. In addition, the (2-4)-th conductive pattern CP2-4′ may be provided as the second bridge pattern BRP2. The second bridge pattern BRP2′ may be a conductive pattern that is integrally provided with the second sensor electrodes TE21 and TE22 that are adjacent to each other.

According to an embodiment of the present invention, the (2-1)-th and (2-3)-th conductive patterns CP2-1′ and CP2-3′ may be electrically connected to the first conductive pattern CP1 through the contact holes CNT1 and CNT2 of the touch insulating layer TS_INS′. For example, the (2-1)-th conductive pattern CP2-1′ may include a first portion CPP1′, which is formed on the touch insulating layer TS_INS′, and a second portion CPP2′, which is formed inside the first contact hole CNT1. The second portion CPP2′ may include a coating layer CTL that is in contact with an inner surface of the first contact hole CNT1 and that includes MXenes. The MXenes of the coating layer CTL may have a first concentration. In addition, the second portion CPP2′ may include a via layer VAL that is formed on the coating layer CTL and that includes MXenes. The MXenes of the via layer VAL may have a second concentration that is different from the first concentration. The first concentration of the MXenes of the coating layer CTL may be lower than the second concentration of the MXenes of the via layer VAL. The relatively low concentration of the MXenes may easily reach a lower portion of the first contact hole CNT1 that is in contact with the first conductive pattern CP1, thereby forming the coating layer CTL surrounding inner surfaces of the first contact hole CNT1. For example, the coating layer CTL may be disposed between the via layer VAL and the first conductive pattern CP1.

The coating layer CTL may extend along an inner surface of the first contact hole CNT1 to be in contact with the first conductive pattern CP1 within the second portion CPP2′. In addition, the coating layer CTL may extend from the inner surface of the first contact hole CNT1 to contact the touch insulating layer TS_INS' within the first portion CPP1′. For example, the first portion CPP1′ my include the coating layer CTL that is disposed on the touch insulating layer TS_INS′. The coating layer CTL is a composition including MXenes or an organic composition in which MXenes are dispersed, and may be formed through a liquid process.

The via layer VAL may be in contact with the coating layer CTL. The via layer VAL may be spaced apart from the first conductive pattern CP1 with the coating layer CTL interposed therebetween in the second portion CPP2′. In addition, the via layer VAL may be spaced apart from the touch insulating layer TS_INS' with the coating layer CTL interposed therebetween in the first portion CPP1′. For example, the first portion CPP1′ my include the via layer VAL that is disposed on the coating layer CTL. The via layer VAL may include a relatively high concentration of MXenes compared to the MXenes of the coating layer CTL. However, a portion of the (2-1)-th conductive pattern CP2-1′ forming the via layer VAL is not limited to MXenes. For example, the via layer VAL may include metals such as molybdenum, silver, titanium, copper, aluminum, and an alloy thereof. In addition, the via layer VAL may include a transparent conductive oxide such as an indium tin oxide (ITO), an indium zinc oxide (IZO), a zinc oxide (ZnO), and an indium tin zinc oxide (ITZO).

As described above, the inner surfaces of the contact holes CNT1 and CNT2 of the touch insulating layer TS_INS' may be more effectively coated through a relatively low concentration of MXenes. For example, the first conductive pattern CP1 and the second conductive patterns CP2 may be more stably connected to each other through MXenes that are disposed in the contact holes CNT1 and CNT2. In addition, MXenes that are disposed on the inner surfaces of the contact holes CNT1 and CNT2 may reduce light blocking by a metal pattern, thereby increasing light efficiency.

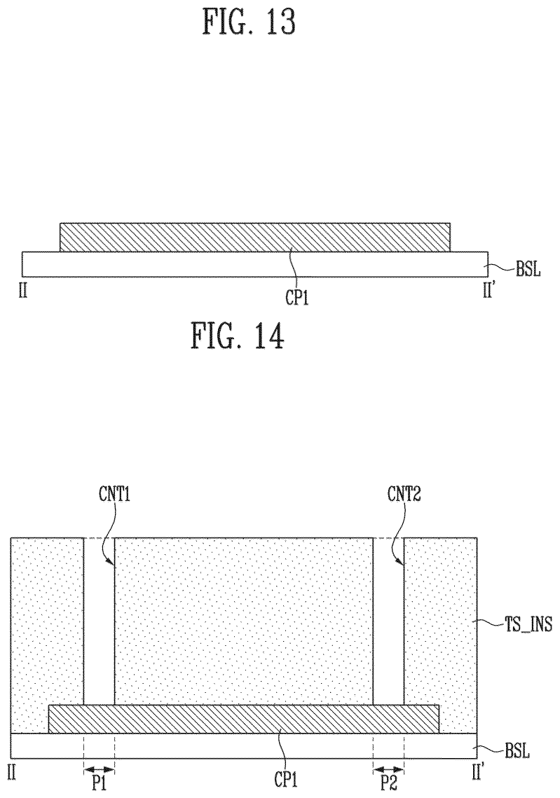

FIG. 13 to FIG. 17 illustrate a manufacturing method of the display device according to an embodiment of the present invention.

Hereinafter, a manufacturing method of a display device including the sensing panel TSP (or touch sensor) described with reference to FIG. 8, FIG. 9, FIG. 10, and FIG. 11 will be described with reference to FIG. 13 to FIG. 17. In describing FIG. 13 to FIG. 17, descriptions of contents overlapping the contents described with reference to FIG. 8, FIG. 9, FIG. 10, and FIG. 11 will be omitted or briefly discussed.

Before forming the base layer BSL, as shown in FIG. 3, the substrate SUB may be provided, and the pixel circuit layer PCL and the display element layer DPL may be formed on one surface of the substrate SUB to form the pixels PXL. Thereafter, the thin film encapsulation layer TFE may be formed on one surface on which the pixels PXL are formed.

Referring to FIG. 9 and FIG. 13, after the pixels PXL are formed, the base layer BSL may be formed on the thin film encapsulation layer TFE (see FIG. 4). However, the present invention is not limited thereto. For example, the base layer BSL may be the thin film encapsulation layer TFE.

Thereafter, the first conductive pattern CP1 may be formed on the base layer BSL. For example, the first conductive pattern CP1 may have a single-layered structure including a metal layer or a transparent conductive layer. However, the first conductive pattern CP1 is not limited to a single-layered structure. For example, the first conductive pattern CP1 may have a multi-layered structure in which titanium (Ti)/aluminum (Al)/titanium (Ti) are sequentially stacked on each other.

Referring to FIG. 9 and FIG. 14, the touch insulating layer TS_INS may be formed on the base layer BSL. Subsequently, the contact holes CNT1 and CNT2 penetrating the touch insulating layer TS_INS may be formed. The contact holes CNT1 and CNT2 may expose the portions P1 and P2 of the first conductive pattern CP1 on the first conductive pattern CP1.

For example, the touch insulating layer TS_INS may form the contact holes CNT1 and CNT2 through a photolithography process to expose the portions P1 and P2 of the first conductive pattern CP1. For example, by forming a photoresist film on the touch insulating layer TS_INS and then performing exposure and development processes through a mask, the photoresist film may be patterned to form photoresist patterns with regular intervals. Areas removed from the photoresist film may be areas in which the contact holes CNT1 and CNT2 are formed. Portions of the touch insulating layer TS_INS that do not overlap the photoresist patterns may be removed through an etching process to form the contact holes CNT1 and CNT2 exposing the portions P1 and P2 of the first conductive pattern CP1. The contact holes CNT1 and CNT2 may be formed by etching the touch insulating layer TS_INS that is exposed by the photoresist patterns until the portions P1 and P2 of the first conductive pattern CP1 are exposed. After the contact holes CNT1 and CNT2 are formed, photoresist patterns remaining on the touch insulating layer TS_INS may be removed.

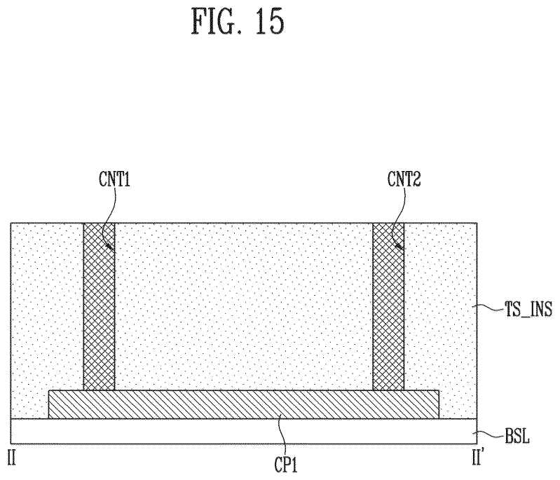

Referring to FIG. 9 and FIG. 15, the second conductive patterns CP2 including MXenes may be formed inside the contact holes CNT1 and CNT2. The (2-1)-th conductive pattern CP2-1 including MXenes may be formed inside the first contact hole CNT1, and the (2-3)-th conductive pattern CP2-3 including MXenes may be formed inside the second contact hole CNT2. For example, MXenes having organic dispersion ink characteristics may be coated on the inner surfaces of the contact holes CNT1 and CNT2 through a liquid process. The MXenes may be disposed to cover the inner surfaces of the contact holes CNT1 and CNT2. For example, the process of providing MXenes may be spray coating, spin coating, inkjet printing, or the like, but the present invention is not limited thereto. The formed MXenes may then be cured at low temperatures (for example, in the range of 120° C. to 130° C.). As such, the inside of the contact holes CNT1 and CNT2 may be filled with the second conductive patterns CP2 including MXenes. For example, a portion of the (2-1)-th conductive pattern CP2-1 may be formed to cover the inner surfaces of the first contact hole CNT1. A portion of the (2-3)—the conductive pattern CP2-3 may be formed to cover the inner surfaces of the second contact hole CNT2. Accordingly, the second conductive patterns CP2 including MXenes may substantially completely cover the inner surfaces of the contact holes CNT1 and CNT2.

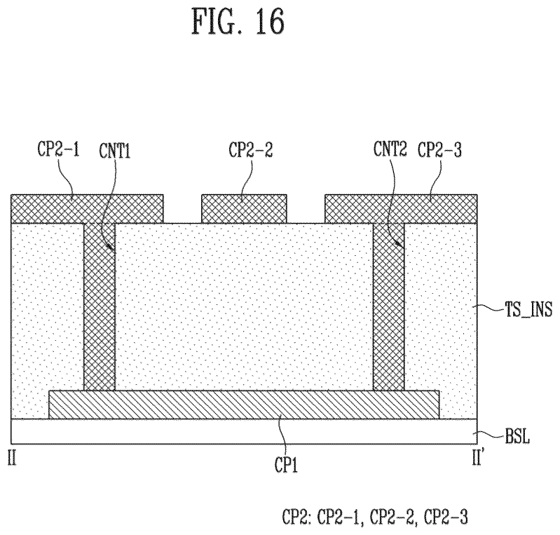

Referring to FIG. 9 and FIG. 16, the second conductive patterns CP2 may be formed on the touch insulating layer TS_INS. In addition, the second conductive patterns CP2 including MXenes may be cured at low temperatures (for example, in the range of about 120° C. to about 130° C.). As the MXenes are reflowed through the curing process, a portion of the second conductive patterns CP2 may cover the inner surfaces of the contact holes CNT1 and CNT2. For example, the portion of the second conductive patterns CP2 may completely cover the inner surfaces of the contact holes CNT1 and CNT2.

For example, as shown in FIG. 12, when the second conductive patterns CP2 including MXenes having different concentrations are sequentially filled in the contact holes CNT1 and CNT2, after disposing the MXenes with the first concentration and performing a curing process, the MXenes with the second concentration may be provided and the curing process may be performed again.

Thereafter, the second conductive patterns CP2 may be patterned using a mask to form the first sensor electrodes TE11 and TE12 and the second bridge pattern BRP2 on the touch insulating layer TS_INS. For example, a photoresist film exposing an area excluding an area in which the (2-1)-th conductive pattern CP2-1, the (2-2)-th conductive pattern CP2-2, and the (2-3)-th conductive pattern CP2-3 are to be formed may be formed on the touch insulating layer TS_INS. The photoresist film may be patterned by performing exposure and development processes through a mask. After the (2-1)-th to (2-3)-th conductive patterns CP2-1 to CP2-3 are formed, the photoresist layer that is formed on the touch insulating layer TS_INS may be removed.

Accordingly, the (2-1)-th conductive pattern CP2-1 connected to the first conductive pattern CP1 through the first contact hole CNT1 may be provided. In addition, the (2-3)-th conductive pattern CP2-3 connected to the first conductive pattern CP1 through the second contact hole CNT2 may be provided.

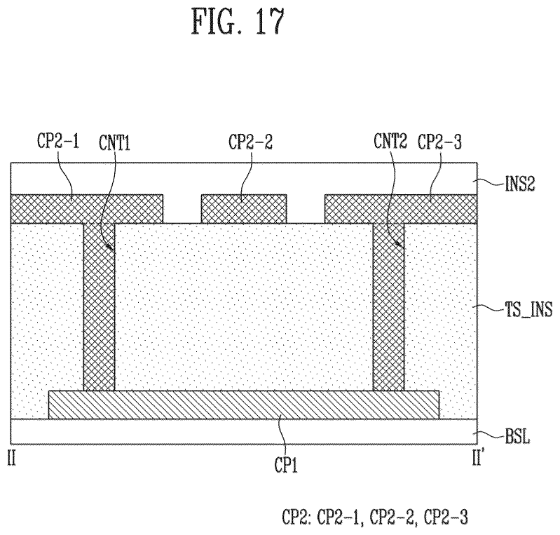

Referring to FIG. 17, the touch insulating layer TS_INS and the second insulating layer INS2 covering the second conductive patterns CP2 may be formed. The second insulating layer INS2 may be formed on the touch insulating layer TS_INS. For example, the second insulating layer INS2 may be in direct contact with the second conductive patterns CP2.

The touch sensor according to embodiments of the present invention may form second conductive patterns including MXenes with high transmittance and conductivity inside the contact holes of the touch insulating layer. Accordingly, the touch sensor according to the embodiments of the present invention may provide a stable electrical connection by more effectively preventing the contact defects between the first conductive pattern and the second conductive pattern through the MXenes that are formed in the contact holes. In addition, by forming MXenes instead of metal in the contact holes, light efficiency can be increased by reducing light blocking that may be caused by a metal pattern.

Although certain embodiments and implementations have been described herein, other embodiments and modifications will be apparent from this description. Accordingly, the present invention is not limited to the embodiments, but rather to the broader scope of the presented claims and various obvious modifications and equivalent arrangements.

According to the embodiments of the present invention, it is possible to provide a display device including a touch sensor with increased sensing sensitivity.

Effects of embodiments of the present invention are not limited by what is illustrated in the above, and more various effects are included in the present specification.

While the present invention has been particularly shown and described with reference to embodiments thereof, it will be apparent to those of ordinary skill in the art that various changes in form and detail may be made thereto without departing from spirit and scope of the present invention.

What is claimed is:

1. A display device comprising:
a substrate;
pixels formed on the substrate;
a base layer formed on the pixels;
a first conductive pattern disposed on the base layer;
a touch insulating layer formed on the base layer and the first conductive pattern and having contact holes that overlap portions of the first conductive pattern; and
second conductive patterns formed on the touch insulating layer and electrically connected to the first conductive pattern through the contact holes,
wherein some of the second conductive patterns are formed inside the contact holes, and
the second conductive patterns include MXenes.

2. The display device of claim 1, wherein the second conductive patterns includes a (2-1)-th conductive pattern and a (2-2)-th conductive pattern,
wherein each of the (2-1)-th and (2-2)-th conductive patterns includes:
a first portion formed on the touch insulating layer; and
a second portion formed inside one of the contact holes, and
the second portion includes the MXenes.

3. The display device of claim 2, wherein
the first portion includes the MXenes.

4. The display device of claim 2, wherein
the second portion includes a coating layer that is disposed on an inner surface of one of the contact holes and has the MXenes, and
the MXenes of the coating layer has a first concentration.

5. The display device of claim 4, wherein
the second portion includes a via layer that is formed on the coating layer and has the MXenes, and
the MXenes of the via layer has a second concentration that is different from the first concentration.

6. The display device of claim 5, wherein
the first concentration is lower than the second concentration.

7. The display device of claim 4, wherein
the coating layer extends along the inner surface of the one of the contact holes to contact the first conductive pattern.

8. The display device of claim 4, wherein
the coating layer extends from the inner surface of the one of the contact holes to contact an upper surface of the touch insulating layer and is included in the first portion.

9. The display device of claim 1, wherein
the second conductive patterns include an inorganic compound with a two-dimensional planar structure.

10. The display device of claim 1, wherein
the contact holes penetrate the touch insulating layer between one of the second conductive patterns and the first conductive pattern and between the other one of the second conductive patterns and the first conductive pattern.

11. The display device of claim 1, wherein
the contact holes have an aspect ratio of 1 or more.

12. The display device of claim 1, wherein
the touch insulating layer includes an organic insulating material.

13. A manufacturing method of a display device, the method comprising:
providing a substrate;
forming pixels on the substrate;
providing a base layer on the pixels;
forming a first conductive pattern on the base layer;
forming a touch insulating layer having contact holes that overlap portions of the first conductive pattern on the base layer; and
forming second conductive patterns on the touch insulating layer, wherein the second conductive patterns are electrically connected to the first conductive pattern through the contact holes,
wherein some of the second conductive patterns are formed inside the contact holes, and
the second conductive patterns include MXenes.

14. The manufacturing method of the display device of claim 13, wherein the forming of the second conductive patterns further includes curing the MXenes at a low temperature.

15. The manufacturing method of the display device of claim 13, wherein the contact holes have an aspect ratio of 1 or more.

16. A display device comprising:
a display panel; and
a sensing panel disposed on the display panel,
wherein the sensing panel includes:
a base layer;
a first conductive pattern disposed on the base layer;
a touch insulating layer formed on the base layer and having first and second contact holes that overlap portions of the first conductive pattern; and
(2-1)-th and (2-2)-th second conductive patterns formed on the touch insulating layer and electrically connected to the first conductive pattern through the first and second contact holes,
wherein the (2-1)-th and (2-2)-th second conductive patterns are respectively disposed in the first and second contact holes, and
each of the (2-1)-th and (2-2)-th second conductive patterns include MXenes.

17. The display device of claim 16, wherein each of the (2-1)-th and (2-2)-th second conductive patterns includes a coating layer and a via layer, wherein the coating layer is disposed on the touch insulating layer and inside the first and second contact holes, and wherein via layer is disposed on the coating layer.

18. The display device of claim 17, wherein the via layer is disposed inside the first and second contact holes.

19. The display device of claim 17, wherein the coating layer contacts the first conductive pattern.

20. The display device of claim 17, wherein the coating layer is disposed between the via layer and the first conductive pattern.
